(19) United States
(12) Patent Application Publication
(10) Pub. No.: US 2022/0373899 A1
(43) Pub. Date: Nov. 24, 2022

(54) PROJECTION EXPOSURE APPARATUS WITH A THERMAL MANIPULATOR

(71) Applicant: Carl Zeiss SMT GmbH, Oberkochen (DE)

(72) Inventors: Stephanus Fengler, Aalen (DE); Reimar Finken, Westhausen (DE); Ulrich Loering, Ulm (DE)

(21) Appl. No.: 17/815,801

(22) Filed: Jul. 28, 2022

Related U.S. Application Data
(63) Continuation of application No. PCT/EP2021/053029, filed on Feb. 9, 2021.

(30) Foreign Application Priority Data
Feb. 12, 2020 (DE) 102020201723.9

(51) Int. Cl. G03F 7/20

(52) U.S. Cl. CPC G03F 7/70891; G03F 7/7015; G03F 7/706

(57) ABSTRACT

A microlithographic projection exposure apparatus comprises a projection lens for projecting structures of a mask into a substrate plane via exposure radiation. At least one optical element of the projection lens is provided with a manipulator configured for the targeted input of thermal energy into the optical element, without one of further optical elements of the projection lens being significantly heated in the process. The projection exposure apparatus furthermore comprises a control device configured for controlling the exposure radiation and for controlling the manipulator so that an effect on an optical property of the projection lens that is caused by a decrease in a thermal energy input into the projection lens due to an exposure pause is at least partly compensated for by the energy input via the manipulator. Furthermore, the disclosure relates to a corresponding method for controlling a microlithographic projection exposure apparatus.

### CROSS-REFERENCE TO RELATED APPLICATIONS

The present application is a continuation of, and claims benefit under 35 USC 120 to, international application PCT/EP2021/053029, filed Feb. 9, 2021, which claims benefit under 35 USC 119 of German Application No. 10 2020 201 723.9, filed Feb. 12, 2020. The entire disclosure of these applications are incorporated by reference herein.

### FIELD

The disclosure relates to a microlithographic projection exposure apparatus comprising a projection lens for projecting structures into a substrate plane via exposure radiation. At least one optical element of the projection lens is provided with a manipulator configured for the input of thermal energy into the optical element. Furthermore, the disclosure relates to a method for controlling such a projection exposure apparatus.

### BACKGROUND

A projection exposure apparatus can be used to produce extremely small structures on a substrate during fabrication of integrated circuits or other micro- or nanostructured components. For this purpose, a projection lens of the projection exposure apparatus images structures of a mask or of a reticle onto a photosensitive layer of the substrate during a predefined exposure time interval. In general, a so-called wafer composed of semiconductor material is used as substrate. After an exposure has been carried out, usually there is a change in position or a change of substrate for a further exposure.

With advancing miniaturization of the semiconductor structures and a desire for faster fabrication processes with shorter exposure times, increasingly more stringent desired properties are often being made in respect of the imaging properties of projection exposure apparatuses, and in particular projection lenses. Therefore, projection lenses with the smallest reasonably possible imaging aberrations are desired for imaging mask structures onto the wafer as precisely as possible. In addition to imaging aberrations due to manufacturing or mounting tolerances, imaging aberrations that occur during operation are also known. In this regard, the relatively unavoidable absorption of part of the electromagnetic radiation used for the exposure in optical elements of the projection exposure apparatus can result in generally inhomogeneous heating of the optical elements. This heating of lens elements or mirrors is also referred to as “lens heating” and can cause local changes in the refractive index, expansions and mechanical stresses, and thus aberrations in a wavefront propagating in the projection lens.

Various optical manipulators can be used for at least partially correcting wavefront aberrations that occur during operation. In this regard, for example, DE 10 2015 201 020 A1 discloses manipulators having a multiplicity of individually heatable zones in an optical element. In the case of these thermal manipulators, a heat input is caused for example via infrared radiation or electrical conductor tracks and resistive structures. Certain other known manipulators make it possible to deform a surface or to change a position of an optical element in one or more of the six rigid body degrees of freedom. Manipulators can enable the optical effect of the respective optical element to be established by way of a corresponding state change during operation of the projection exposure apparatus. Depending on the aberration characteristic of the projection lens, which is measured or determined by a simulation, a wavefront deformation that is at least partly suitable for compensating for the currently occurring wavefront aberration can be induced in this way during operation.

A relatively constant alternation between exposure times and exposure pauses without exposure radiation usually takes place during the operation of the projection exposure apparatus. A change of wafer can take place in a pause, for example. The relatively constant alternation between exposure times and exposure pauses causes rapidly changing, thermally dictated imaging aberrations. This effect is also referred to as “fast lens heating” and can lead to a fast periodic change in imaging properties and thus to corresponding imaging aberrations. In the case of the known projection exposure apparatuses, often these imaging aberrations can be compensated for only relatively poorly, or not at all, via manipulators since the related measurements or simulations of imaging properties and the calculation and setting of corresponding travels for the manipulators can be too time-intensive.

### SUMMARY

The disclosure seeks to provide an apparatus and a method which can address shortcomings with certain known systems and, for example, lead to a reduction of imaging aberrations caused by the constant alternation between exposure times and exposure pauses of a projection exposure apparatus.

The disclosure provides, for example, a microlithographic projection exposure apparatus comprising a projection lens for projecting structures into a substrate plane via exposure radiation, wherein at least one optical element of the projection lens is provided with a manipulator configured for the targeted input of thermal energy into the optical element, without one of further optical elements of the projection lens being significantly heated in the process. Furthermore, the projection exposure apparatus comprises a control device configured for controlling the exposure radiation and for controlling the manipulator in such a way that an effect on an optical property of the projection lens that is caused by a decrease in a thermal energy input into the projection lens on account of an exposure pause is at least partly compensated for by the energy input via the manipulator.

In other words, the control device is configured for controlling the manipulator in such a way that an effect, relating to an optical property of the projection lens, of a decrease in a thermal energy input into the projection lens on account of an exposure pause is at least partly compensated for by the energy input via the manipulator. The desire to have thermal energy input into the optical element in a targeted manner, without a further optical element of the projection lens being significantly heated in the process, should be understood to mean that in the process no thermal energy is input into the optical element or only a thermal energy amounting to at most 5%, in particular at most 1%, of the energy input into the first optical element is input into the further optical element.

The optical element of the projection lens is for example a lens element in the form of a wavefront-shaping lens element, a plane plate that is transmissive to the exposure radiation, or a mirror element. The manipulator can make it possible to input a specific thermal energy for different sections or zones of the optical element in such a way that heating takes place with a corresponding change in optical properties. A predefined change in temperature for a section or a zone is also referred to as travel for this section or this zone.

An exposure pause should be understood to mean a time segment in which the intensity of the exposure radiation in the projection lens is reduced or brought down and thus, in the latter case, no exposure radiation passes through the projection lens. The decrease in the thermal energy input on account of the exposure pause is at least partly caused by the decrease in the intensity of the exposure radiation in the exposure pause.

In other words, according to the disclosure, the effect of a decrease in a thermal energy input into the projection lens caused by an exposure pause is at least partly compensated for in a targeted manner. This can be done via a manipulator configured to input thermal energy into the optical element in a targeted manner. The form of operation of the projection lens according to the disclosure can also be referred to for short as “anti-cyclic heating of the optical element”. Heating can take place for example when no exposure takes place, thus anti-cyclically with respect to the individual exposure periods. The targeted input of thermal energy into the optical element, without one of further optical elements of the projection lens being significantly heated in the process, can enable the effect of the exposure pause on the projection lens to be precisely compensated for, such that the optical reaction of the optical element to the thermal energy that is input can be accurately predicted and is not corrupted by less accurately known optical reactions of further optical elements.

In comparison with the conventional wavefront correction via an optimization method referred to as “lens model”, in which a wavefront deviation of the projection lens is determined in specific time segments and is then corrected via suitable manipulator alterations, the wavefront aberrations that occur as a result of the exposure pauses can be corrected much more rapidly by the form of operation according to the disclosure, or their occurrence can be completely avoided. The reason for the longer time scale in the case of the conventional wavefront correction is that firstly a wavefront deviation has to be established as a result of the thermal alterations that occur in the relevant optical element in the exposure pause, which wavefront deviation can then in turn only be corrected by way of suitable manipulator alterations calculated via the “lens model”. In the case of the thermal energy input according to the disclosure into the optical element, a corresponding wavefront deviation can be at least partly prevented from forming.

In the case of relatively thick optical elements, the fast switching-on and -off of the exposure radiation that takes place during operation of a projection exposure apparatus scarcely leads to short-term temperature fluctuations that alter imaging properties. Rather, during operation, these optical elements are heated up to a thermal equilibrium. Imaging aberrations caused by the heating can generally be compensated for with the aid of a suitable setting of manipulators which are determined via control methods known from the prior art.

The disclosure involves the insight that the fast switching-on and -off of the exposure radiation that takes place during operation of a projection exposure apparatus, unlike in the case of relatively thick optical elements, in the case of thin lens elements or other thin optical elements, during each exposure interval, heating can occur as a result of exposure radiation and cooling can occur in the intervening exposure pauses, which can cause rapidly changing, thermally dictated imaging aberrations.

This effect can lead to the “fast lens heating” mentioned in the introduction, which in turn can have the consequence of a fast periodic change in imaging properties and thus the consequence of corresponding imaging aberrations. As already mentioned, in the case of the known projection exposure apparatuses, these imaging aberrations can be compensated for only poorly, or not at all, by manipulators controlled via a “lens model” since the related measurements or simulations of imaging properties and the calculation and setting of corresponding travels for the manipulators are too time-intensive.

The at least partial compensation according to the disclosure of a decrease in a thermal energy input into the projection lens on account of an exposure pause by way of energy input via the manipulator can make it possible to reduce imaging aberrations produced by the constant alternation between exposure times and exposure pauses in projection lenses having thin optical elements.

In accordance with one embodiment, the effect that is at least partly compensated for by the energy input via the manipulator can comprise alterating a wavefront aberration of the projection lens on account of the exposure pause. In accordance with a further embodiment, the projection exposure apparatus furthermore comprises a wavefront determining device for determining a wavefront deviation of the projection lens from a target wavefront, wherein the control device is furthermore configured to correct a wavefront deviation of the projection lens from a target wavefront via the manipulator and/or at least one further manipulator of the projection lens.

In accordance with a further embodiment, the temporal profile of the effect of the energy input caused via manipulator is coordinated with the temporal profile of the effect of the exposure pause on the optical property of the projection lens. In particular, the temporal profile of the effect of the energy input is coordinated with the temporal profile of the effect of the exposure pause on the wavefront aberration of the projection lens.

In accordance with a further embodiment, the optical element provided with the manipulator has a subaperture ratio of at least 0.4, in particular a subaperture ratio of more than 0.75 or of more than 0.9. As known to the person skilled in the art from US2013/0188246A1, for example, the subaperture ratio of an optical element is formed by the quotient of subaperture diameter and optically free diameter. The subaperture diameter is given by the maximum diameter of a respective surface which is illuminated when imaging any point, but one chosen specifically, in the object field on the optical element. The optically free diameter is the diameter of the smallest circle around a respective reference axis of the corresponding optical element which contains the part of the optical element illuminated when imaging the whole object field.

A subaperture ratio of greater than 0.75, for instance, means an arrangement in the pupil plane or a near-pupil arrangement, a subaperture ratio of less than 0.25 means an arrangement in the field plane or a near-field arrangement, and a subaperture arrangement in between means an intermediate arrangement of the optical element between field and pupil planes. A subaperture ratio of at least 0.4 thus includes an intermediate arrangement and a near-pupil arrangement.

In accordance with a further embodiment, the optical element provided with the manipulator has a central thickness of at most 10 mm, such as a central thickness of at most 8 mm or at most 5 mm. The central thickness of the optical element should be understood to mean the dimension of the optical element in the direction of the optical beam path of the projection lens in the region of the optical axis of the optical element or in a region of the optical element that is arranged centrally relative to the cross section of the optical beam path. In general, the thinner an optical element, the faster local heating takes place during action of exposure radiation and cooling of the heated region takes place without exposure radiation.

In accordance with a further embodiment, the optical element provided with the manipulator is assigned at least one further optical element from among the optical elements of the projection lens to the effect that the assigned further optical element has a subaperture ratio which deviates from a subaperture ratio of the optical element provided with the manipulator by a maximum of 0.3, wherein the assigned further optical element has a central thickness of at most 10 mm. For example, the subaperture ratios deviate from one another by a maximum of 0.2 or by a maximum of 0.1. If, for instance, the optical element provided with the manipulator is situated in the pupil plane, then the designated further optical element is likewise situated in the pupil plane or only at a slight distance therefrom. In accordance with various embodiment variants, the assigned further optical element has a central thickness of at most 8 mm or at most 5 mm. In accordance with one embodiment variant, the central thickness of the optical element provided with the manipulator deviates from the central thickness of the assigned optical element by at most 5 mm, in particular by at most 2 mm.

In accordance with a further embodiment, the assigned further optical element is configured as a meniscus lens element arranged in front of a concave mirror. As is known to the person skilled in the art, a meniscus lens element should be understood to mean a lens element which combines a concave surface with a convex surface. In this case, the refractive power of such a meniscus lens element can be positive or else negative. In accordance with one embodiment, the concave mirror constitutes the main mirror of the projection lens, i.e. the mirror having the highest refractive power in the projection lens.

In accordance with a further embodiment, the assigned further optical element has a subaperture ratio of at least 0.4, for example a subaperture ratio of more than 0.75 or of more than 0.9. A subaperture ratio of more than 0.75 is also taken to mean that the optical element is arranged near the pupil.

In accordance with a further embodiment, the at least one further assigned optical element comprises a lens element arranged in the first third of the projection lens, a lens element arranged in the last third of the projection lens and/or a lens element arranged in front of a concave mirror. In other words, a lens element arranged in the first third of the projection lens, a lens element arranged in the last third of the projection lens and/or a lens element arranged in front of a concave mirror can form the above-described assigned optical element or a plurality of such assigned optical elements. The subdivision of the projection lens into different thirds is effected on the basis of the length of the beam path in the projection lens.

In accordance with a further embodiment, the projection exposure apparatus is configured for operation in the DUV wavelength range. For example, the operating wavelength of the projection exposure apparatus is approximately 248 nm or approximately 193 nm.

In accordance with one embodiment, the projection exposure apparatus furthermore comprises a determining device configured for determining a thermal intensity distribution input into the optical element during an exposure process by the exposure radiation. The determining device can comprise a simulation module for calculating the thermal energy distribution input into the element during the exposure process by the exposure radiation. Alternatively, the thermal energy distribution that is input can also be determined by measurement by a suitable measurement apparatus of the determining device or a combination of measurement and simulation and/or calculation. As is known to the person skilled in the art, a thermal intensity distribution is understood to mean the spatial energy distribution transmitted to the optical element per unit time and per unit area.

In a further embodiment, the control device is configured to effect the control of the manipulator on the basis of the thermal intensity distribution determined. By way of example, the manipulator is controlled in such a way that a thermal energy input generated by the manipulator substantially corresponds to the thermal intensity distribution determined. In other words, with the aid of the manipulator, the thermal intensity distribution determined is substantially maintained even during an exposure pause. Via this measure, control can be effected in such a way that a temperature distribution in the optical element does not change, or changes only insignificantly, as a result of switching-on and -off of the exposure radiation.

In accordance with a further embodiment, the control device is configured for controlling the manipulator in such a way that the energy input is effected with a distribution that is spatially resolved over an optically effective area of the optical element. By way of example, the manipulator is designed for heating individual sections or zones of the optical element. The control device can then be configured in such a way that each section or each zone is individually heated so that a predefined thermal intensity distribution or a predefined spatially resolved temperature profile is generated.

In accordance with a further embodiment, the control device is configured to effect the energy input caused via the manipulator within a time period in which at most 10% of a wavefront deviation corresponding to the decrease in the thermal energy input would form or forms in the projection lens. In particular, the control device is configured to effect the energy input caused within a time period in which at most 1% or at most 0.1% of the wavefront deviation corresponding to the decrease in the thermal energy input forms. The wavefront deviation corresponding to the decrease in the thermal energy input should be understood to mean that wavefront deviation of the projection lens which forms after a certain time period without the energy input caused via the manipulator. This time period is used by the optical element in order to adopt a new thermal equilibrium on account of the absence of a thermal energy input.

According to a further embodiment of the projection exposure apparatus, the control device is configured to effect the thermal energy input over a time period of at most 15 seconds. For example, the control device is configured to effect the thermal energy input over a time period of at most 10 seconds, at most 7 seconds or at most 5 seconds. In other words, the energy input by the manipulator is ended after a maximum of 15, 10, 7 or 5 seconds. According to one embodiment, a time period without energy input by the manipulator is at least as long as the time period of the energy input.

In a further embodiment according to the disclosure, the control device is configured to effect the thermal energy input over a time period of at least 2 seconds. For example, the control device is configured to effect the thermal energy input over a time period of at least 3 seconds or at least 5 seconds. For example, it is possible to provide a periodic energy input in each exposure pause between two exposures.

In accordance with a further embodiment, the projection exposure apparatus furthermore comprises a wavefront determining device for determining a wavefront deviation of the projection lens from a target wavefront. Furthermore, the control device is configured to correct a wavefront deviation of the projection lens from a target wavefront via the manipulator and/or at least one further manipulator of the projection lens. The wavefront determining device can comprise for example a measurement apparatus, a simulation module or both for determining the wavefront deviation. A simulation by the simulation module is based for example on a suitable “lens model” known to the person skilled in the art. The measurement apparatus can be designed for example to implement a phase-shifting interferometry technique, such as, for instance, shearing interferometry, or point diffraction interferometry.

In accordance with a further embodiment, the optical element is configured as a plane-parallel plate, also called plane plate. In accordance with a further embodiment, a plurality of optical elements of the projection lens are each configured as a plane-parallel plate. In particular, each of the optical elements configured as a plane-parallel plate is provided with a manipulator configured for the input of thermal energy into the optical element.

According to a further embodiment of the projection exposure apparatus, the manipulator comprises heating elements for the thermal energy input into the optical element. The heating elements are electrically operated heating elements, for example. In the case of such heating elements, a current supply can be provided via electrical conductors or inductively. In the case of electrical heating, an energy input can be controlled with the aid of corresponding control of a heating current. Furthermore, according to one embodiment, the optical element comprises quartz bodies. A temperature increase in quartz results in an increase in the refractive index. In accordance with one embodiment variant, the heating power of the heating elements is between 10 W/m² and 150 W/m², for example between 50 W/m² and 100 W/m². In accordance with a further embodiment variant, the total power of the heating elements is between 0.2 W and 5 W, for example between 0.5 W and 2.0 W.

In accordance with one embodiment of the disclosure, the projection lens comprises a further optical element with a manipulator configured for the input of thermal energy into the optical element and the two optical elements are embodied as plane-parallel plates, each having a multiplicity of heatable zones. Optionally, the heatable zones are arranged in a manner distributed over a cross section of the exposure beam path of the projection lens. According to one embodiment, for each zone, very small electrically conductive structures and resistive structures are provided in the case of both plates for electrical heating. Furthermore, an air or gas flow can be guided in the interspace between the two plates for the purpose of cooling the plates.

In accordance with a further embodiment, a gap having a width of at least 3 mm, for example at least 5 mm, is arranged between the optical elements each configured as a plane-parallel plate. In accordance with a further embodiment, the gap width is at most 20 mm or at most 10 mm.

In accordance with a further embodiment, the manipulator comprises an irradiation device for radiating heating radiation onto the optical element. The heating radiation can have a wavelength that differs from the wavelength of the exposure radiation; alternatively, the heating radiation can also have the same wavelength as the exposure radiation.

The heating radiation can be radiated onto the optical element transversely with respect to the beam path of the exposure radiation, i.e. from the edge of the optical element. This procedure is also referred to as “heating by transverse light”. Alternatively, with the aid of mirrors, for example, the heating radiation can be coupled into the region of the exposure beam path and thus be radiated onto the optical element substantially perpendicularly. In an alternative embodiment, the manipulator serves to direct a warm gas flow onto the optical element and thus to input thermal energy into the optical element.

Furthermore, in a further embodiment, the projection exposure apparatus is configured for operation in the UV wavelength range. In particular, the operating wavelength of the projection exposure apparatus is approximately 365 nm, approximately 248 nm or approximately 193 nm. Alternatively, the projection exposure apparatus can be designed for operation in the extreme ultraviolet (EUV) wavelength range with a wavelength of less than 100 nm, for example approximately 13.5 nm or approximately 6.8 nm. A projection exposure apparatus for the EUV wavelength range substantially comprises mirrors as optical elements. Furthermore, by comparison with projection exposure apparatuses for radiation in a different, longer-wavelength spectral range, EUV projection exposure apparatuses usually have significantly fewer optical elements or optical surfaces in order to reduce intensity losses as a result of absorption.

The disclosure also provides, for example, a method for controlling a microlithographic projection exposure apparatus comprising a projection lens and a manipulator for at least one optical element of the projection lens for the targeted input of thermal energy into the optical element, without one of further optical elements of the projection lens being significantly heated in the process. The method comprises controlling an exposure radiation for projecting structures into a substrate plane and controlling the manipulator in such a way that an effect on an optical property of the projection lens that is caused by a decrease in a thermal energy input into the projection lens on account of an exposure pause is at least partly compensated for by the energy input via the manipulator.

One embodiment of the method according to the disclosure furthermore comprises determining a thermal intensity distribution input into the optical element during an exposure process by the exposure radiation, and controlling the manipulator on the basis of the thermal intensity distribution determined.

The features specified in respect of the above-detailed embodiments, exemplary embodiments and embodiment variants, etc., of the projection exposure apparatus according to the disclosure can be accordingly applied to the control method according to the disclosure. These and other features of the embodiments according to the disclosure will be explained in the description of the figures and in the claims. The individual features can be implemented, either separately or in combination, as embodiments of the disclosure. Furthermore, they can describe embodiments which are independently protectable and protection for which is claimed only during or after pendency of the application, as the case may be.

### BRIEF DESCRIPTION OF THE DRAWINGS

The above and further features of the disclosure will be illustrated in the following detailed description of exemplary embodiments according to the disclosure with reference to the accompanying schematic drawings, in which:

FIG. 1 shows a first exemplary embodiment of the microlithographic projection exposure apparatus according to the disclosure comprising a projection lens comprising two plane-parallel optical plates and also in each case a manipulator for heating a multiplicity of zones of each of the plates, in a schematic view;

FIG. 2 shows, in a more detailed schematic view, one of the optical plates of the exemplary embodiment according to FIG. 1;

FIG. 3 shows, in a schematic view, a second exemplary embodiment of the projection exposure apparatus according to the disclosure comprising a thin optical plate as an optical element having heatable zones;

FIG. 4 shows, in a schematic view, various regions having a high intensity of exposure radiation on an optical element of a projection lens;

FIG. 5 shows, in a schematic illustration, a thermal intensity distribution on an optical element determined for the exposure radiation according to FIG. 4;

FIG. 6 shows, in a diagram, the thermal power input into an optical element by exposure radiation and a thermal manipulator during an exposure of a multiplicity of wafers; and

FIG. 7 shows, in a diagram, a comparison of the temporal profile of an offset of the Zernike coefficient Z12 in the case of a projection exposure apparatus according to the disclosure and a conventional projection exposure apparatus during an exposure of a multiplicity of wafers.

### DETAILED DESCRIPTION OF EXEMPLARY EMBODIMENTS

In the exemplary embodiments or embodiments or embodiment variants described below, elements which are functionally or structurally similar to one another are provided with the same or similar reference signs as far as possible. Therefore, for understanding the features of the individual elements of a specific exemplary embodiment, reference should be made to the description of other exemplary embodiments or the general description of the disclosure.

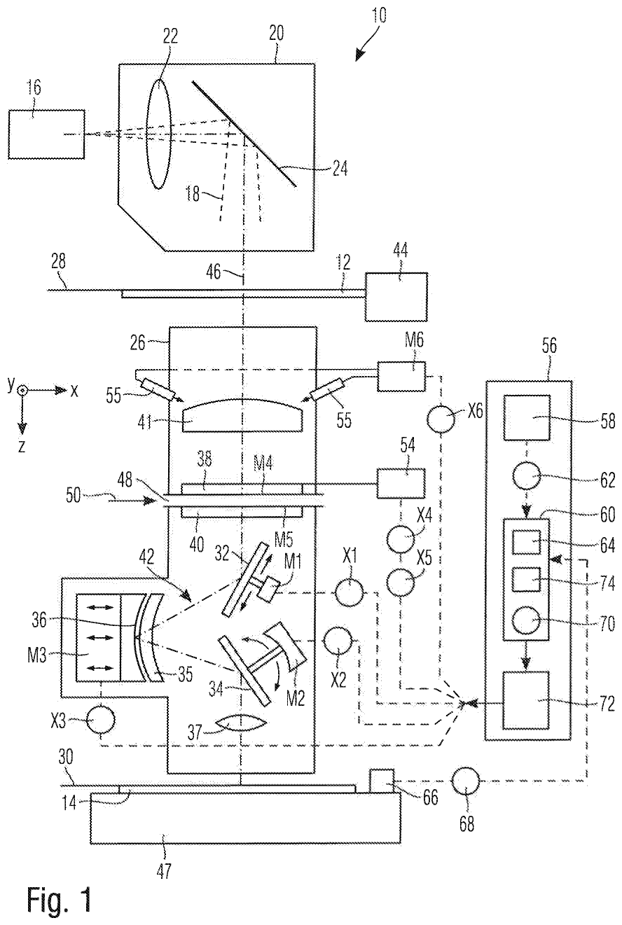

In order to facilitate the description, a Cartesian xyz-coordinate system is indicated in some drawings, from which system the respective positional relationship of the components illustrated in the figures is evident. In FIG. 1, the y-direction runs perpendicular to and out of the plane of the drawing, the x-direction runs toward the right, and the z-direction runs downward.

FIG. 1 shows, in a schematic view, a microlithographic projection exposure apparatus 10 for producing microstructured components such as, for example, integrated circuits. The projection exposure apparatus 10 serves for projecting structures of a mask 12 or of a reticle onto a photosensitive layer of a substrate 14. Wafers composed of silicon or some other semiconductor are usually used as the substrate 14.

For the projection, the projection exposure apparatus 10 contains a radiation source 16 for providing electromagnetic radiation as exposure radiation 18. In this exemplary embodiment, the radiation source 16 provides radiation in the UV range, in particular in the DUV with a wavelength of for example approximately 248 nm or 193 nm, and contains for this purpose e.g. a suitably designed laser. In alternative exemplary embodiments, the radiation source can also be configured for providing radiation in the extreme ultraviolet (EUV) wavelength range with a wavelength of less than 100 nm, in particular approximately 13.5 nm or approximately 6.8 nm.

The exposure radiation 18 coming from the radiation source 16 firstly passes through an illumination system 20 of the projection exposure apparatus 10. The illumination system 20 comprises a multiplicity of optical elements, of which a lens element 22 and a deflection mirror 24 are illustrated symbolically in FIG. 1. A desired illumination of the mask 12 is set by the illumination system 20. Such a setting of the illumination is also referred to as illumination setting. Such an illumination setting defines the angular distribution of the exposure radiation 18 radiated onto the mask 12. Examples of illumination settings include dipole, quadrupole or multipole illumination. Furthermore, the illumination system can contain or make possible a scanner slot for continuously scanning the mask 12 with an exposure beam having a rectangular cross section.

The projection exposure apparatus 10 furthermore contains a projection lens 26 for imaging structures of the mask 12 onto a photosensitive layer of the substrate 14. For this purpose, the structures of the mask 12 are arranged in an object plane 28 and the photosensitive layer is arranged in an image plane 30 of the projection lens 26. The image plane 30 can thus also be referred to as a substrate plane into which the mask structures are projected. For the purpose of imaging the structures, the projection lens 26 contains a multiplicity of optical elements in the form of lens elements, mirrors or the like, of which a lens element 41, a first optical plate 38, a second optical plate 40, a first deflection mirror 32, a concave mirror 36, a meniscus lens element 35 disposed directly in front of the concave mirror 36, a second deflection mirror 34, and a thin converging lens element 37 are illustrated by way of example in FIG. 1. The optical elements of the projection lens 26 define a beam path 42 of the projection lens 26. In accordance with one exemplary embodiment, the concave mirror 26 constitutes the main mirror of the projection lens 26, i.e. it is the mirror having the highest refractive power in the projection lens. In accordance with the exemplary embodiment illustrated in FIG. 1, the lens element 41 is arranged in a first third of the projection lens 26 and the thin converging lens element 37 is arranged in a last third of the projection lens 26. The subdivision of the projection lens 26 is effected here on the basis of the length of the beam path of the exposure radiation 18 in the projection lens 26.

The meniscus lens element 35 has a central thickness of at most 10 mm, in particular of at most 5 mm, and together with the concave mirror 36 forms a so-called Schupmann achromat.

The lens element 41, the optical plates 38 and 40, the thin diverging lens element 36 and also the thin converging lens element 37 are each arranged at a location in the beam path 42 of the projection lens 26 such that they have a subaperture ratio of at least 0.4, in particular of at least 0.7 or at least 0.9, that is to say that they are at a considerable optical distance from the field plane or a conjugate field plane and, in accordance with specific embodiments, are situated near the pupil plane or a conjugate pupil plane of the projection lens 26. Regarding the definition of the subaperture ratio, reference is made to the explanations given above in this text. In accordance with one embodiment, the subaperture ratios of the optical plates 38 and 40 deviate by a maximum of 0.3, in particular a maximum of 0.1, from the respective subaperture ratio of the thin diverging lens element 36, the thin converging lens element 37 and/or the lens element 41.

For holding and exactly positioning the mask 12, the projection exposure apparatus 10 contains a mask mount 44. The mask mount 44 enables a spatial displacement, rotation or inclination of the mask 12 with the aid of actuators, even during operation. Furthermore, for scanning operation the mask mount 44 can be designed for moving the mask 12 perpendicular to an optical axis 46 of the projection lens 26. Correspondingly, a substrate mount 47 is provided for the substrate 14, and is designed for the spatial displacement, rotation or inclination of the substrate 14 via actuators, even during operation. Furthermore, for step-and-scan operation, provision can be made for moving the substrate 14 perpendicular to the optical axis 46.

In order to avoid production defects in the case of micro- or nanostructured components, it is often desirable to minimize imaging aberrations of the projection lens 26 during the imaging of structures of the mask 12 onto the substrate 14. In addition to imaging aberrations due to manufacturing and assembly tolerances, imaging aberrations may also only occur in the projection lens 26 during operation of the projection exposure apparatus 10. In this regard, local heating can occur at individual optical elements as a result of an unavoidable absorption of a portion of the incident or transmitted exposure radiation 18. The heating can cause local changes in the surface geometry as a result of expansion or mechanical stress or bring about a change in material properties such as the refractive index. A further cause of operationally dictated imaging aberrations is ageing effects, for example compression of the material.

Imaging aberrations of lenses are often described as a deviation of a measured optical wavefront from a target wavefront. The deviation is also referred to as wavefront deformation or wavefront aberration and it can be decomposed into individual components by a series expansion, for example. A decomposition into Zernike polynomials has been found to be particularly suitable in this case since the individual terms of the decomposition can be respectively assigned to specific imaging aberrations such as, for instance, astigmatism or coma.

For the compensation of such wavefront aberrations that occur or change during operation, the projection lens 26 contains various manipulators for altering the optical properties of optical elements. A manipulator M1 is arranged for the first deflection mirror 32, which manipulator is configured for displacing the first deflection mirror 32 in a plane and thus in two mutually perpendicular directions. The plane of the displacements is arranged for example parallel to the reflective surface of the first deflection mirror 32 or to the optical axis 46.

The second deflection mirror 34 can be tilted by rotation via a manipulator M2 about an axis parallel to the y-axis. The angle of the reflective surface of the second deflection mirror 34 relative to the incident exposure radiation is thus altered. In other exemplary embodiments, the manipulators M1, M2, M3 can have further degrees of freedom. Generally, the associated optical element 32, 34 can be displaced by way of carrying out a rigid body movement along a predefined travel. By way of example, such an travel can combine translations, tilts or rotations in any manner.

The concave mirror 36 is embodied as a deformable or adaptive mirror. For this purpose, the projection lens 26 comprises a manipulator M3 configured for separately deforming a multiplicity of regions of a reflective coating as zones that are individually settable in terms of the optical effect thereof. A travel for this manipulator M3 describes a specific deformation of the concave mirror 36 by a multiplicity of actuators.

For the first and second transparent optical plates 38, 40, the projection lens 26 contains in each case an electrically operated thermal manipulator, M4 and M5 respectively. Both manipulators M4 and M5 have a multiplicity of electrically conductive and resistive structures in the respective plate for heating local zones. The optical plates 38 and 40 are arranged perpendicular to the optical axis 46 and plane-parallel to one another in the beam path of the projection lens 26. A gap 48, through which an air, gas or liquid flow 50 is guided for cooling purposes, is formed between the optical plates 38, 40.

In this exemplary embodiment, the optical plates 38, 40 are embodied as thin quartz plates having a central thickness of each case approximately 5 mm. The quartz plates can have a uniform thickness, and so the term “thickness” can also be used here instead of the term “central thickness”. Between the quartz plates there is a gap having a width of approximately 7 mm. Alternatively, it is also possible to arrange more than two optical plates, non-plane-parallel plates or lens elements having a multiplicity of heatable zones in a projection lens. In quartz, a temperature increase at wavelengths around 193 nm leads to an increase in the refractive index. This effect is, inter alia, the cause of wavefront aberrations as a result of lens heating. At the optical plates 38, 40, the effect is used for producing a wavefront deformation which is intended to compensate for a currently occurring wavefront aberration in the projection lens 26 caused for example by lens heating in one or more of the optical elements. In other words, the temporal profile of the effect of the energy input caused via the manipulators M4 and/or M5 is coordinated with the temporal profile of the effect of the exposure pause on the optical property of the projection lens 26. However, fast lens heating as described further up can occur at the thin optical plates 38, 40, the meniscus lens 35 and the thin converging lens 37. Heating and cooling occur in the cycle of the exposure times and exposure pauses. This leads to rapidly changing, periodic imaging aberrations.

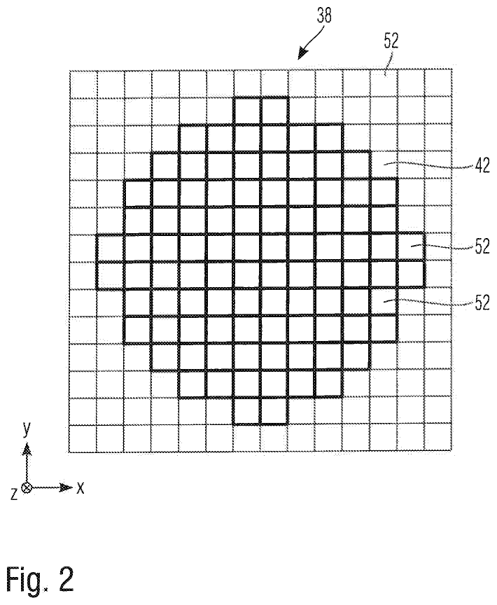

FIG. 2 illustrates a schematic view of the first optical plate 38. The first plate 38 contains a two-dimensional matrix of separately heatable zones 52. In this exemplary embodiment, the first optical plate 38 has a 14×14 matrix of zones 52. Here, ninety-six separately heatable zones 52 are arranged in an optically effective manner in the beam path 42 of the projection lens 26. The second optical plate 40 has a corresponding embodiment such that a total of one hundred and ninety-two heatable zones 52 are arranged in the beam path 42. Alternatively, a different number, arrangement and form of the zones 42 is also possible; by way of example, the zones can be arranged radially or embodied as strips or in a circular arc-shaped manner.

In accordance with one embodiment, the zones 52 are heated in such a way that colder and warmer regions balance one another overall in relation to the ambient temperature. Additionally, zones 52 at the edge of the optical plates 38, 40 with thermal contact to other components of the projection lens 26 are actively heated to the ambient temperature. This ensures a thermal neutrality of the optical plates 38, 40 vis-à-vis the surroundings.

In the following description, reference is made to both FIG. 1 and FIG. 2. The manipulators M4, M5 for the optical plates 38, 40 furthermore contain an actuating device 54 for setting a predefined temperature profile or a thermal intensity distribution for both optical plates 38, 40. Such a temperature profile prescribes temperature values or corresponding values, such as, for instance, a heating power in W/m², as travel for each zone 52 of both optical plates 38, 40. The thermal intensity distribution thus represents a travel. The actuating device 54 supplies each zone 52 of the optical plates 38, 40 with an appropriate heating current for setting the predefined travel and can additionally regulate the cooling by way of the air, gas or liquid flow 50.

On the basis of the temperature profiles that are settable at the optical plates 38 and 40 via the manipulators M4 and M5, thermal energy can be introduced into the relevant optical plate 38 or respectively 40 in a targeted manner, without any other of the optical elements 41, 32, 35, 36, 34, 37 and 40 or respectively 38 arranged in the beam path of the projection lens 26 being significantly heated in the process. This should be understood to mean that in the process either no thermal energy is input into the other optical element, or at most a thermal energy amounting to at most 5%, in particular at most 1%, of the energy input into the optical plate 38 or respectively the optical plate 40 is input.

Furthermore, the projection lens 26 comprises, for the lens element 41, a manipulator M6 configured for heating various zones of the lens element 41 by way of infrared radiation. For this purpose, the manipulator M6 comprises a multiplicity of irradiation units 55, which radiate infrared light provided by an infrared light source of the manipulator M6, with a settable intensity in each case, onto a specific region or a specific zone of the lens element 41. The lens element 41 with the manipulator M6 can be arranged in a field plane or pupil plane of the projection lens 26, or intermediately, i.e. between field plane and pupil plane. A thermal manipulator M6, which radiates infrared light onto a specific region or a zone of the lens element 41, is particularly suitable for exposure radiation in the deep ultraviolet DUV or VUV spectral range and as described for example in US 2008/0204682 A1. Via the manipulator M6, thermal energy can thus be introduced into the lens element 41 in a targeted manner, without any other of the optical elements 38, 40, 32, 35, 36, 34 and 37 arranged in the beam path of the projection lens 26 being significantly heated in the process.

The projection exposure apparatus 10 furthermore contains a control device 56 configured, inter alia, for controlling the exposure radiation 18 and the manipulators M1 to M5. For this purpose, the control device 56 comprises an exposure controller 58 and a manipulator controller 60. With the aid of the exposure controller 58, the illumination system 20 is set in such a way that a desired illumination setting and also exposure time periods and exposure pauses are realized as accurately as possible. Exposure pauses are often used in particular for exchanging wafers. A set illumination setting 62 and also exposure times and exposure pauses are communicated to the manipulator controller 60.

The manipulator controller 60 comprises a wavefront determining device 64 for determining a wavefront deviation of the projection lens 26 from a target wavefront. In this case, wavefronts 68 measured by a wavefront measuring device 66 and other state characterizations are communicated to the wavefront determining device 64 and taken into account when determining the wavefront deviation. The wavefront measuring device can be configured for example to implement a phase-shifting interferometry technique, such as, for instance, shearing interferometry, or point diffraction interferometry. Alternatively or additionally, wavefront deviations calculated by a simulation module 70 with the aid of a lens model can be taken into account. In this way, depending on manipulator positions, a wavefront deviation can be determined even before or between a wavefront measurement.

For the compensation of wavefront deviations determined, a travel generator 72 is used to determine optimum travels X1 to X5 for each manipulator M1 to M5. In this case, suitably designed optimization methods known to the person skilled in the art can be used, which are also known as “lens model”. The travels X1 to X5 determined are subsequently communicated to the manipulators M1 to M5, which then carry out a corresponding setting of the optical elements 32 to 41. In this way, it is possible for example to compensate for imaging aberrations of the projection lens 26 which occur on account of slow heating of the optical elements or of other components across a plurality of exposure time periods and exposure pauses or are caused by aging effects such as compaction of optical materials. However, this procedure is not suitable for correcting imaging aberrations as a result of fast lens heating.

For compensation of such momentary, periodic wavefront deviations that occur as a result of fast lens heating at the two optical plates 38, 40, the control device 56 additionally comprises a determining device 74 for determining a thermal intensity distribution input into the first and second optical plates 38, 40 by the exposure radiation. The determination is effected taking account of the illumination setting 62 communicated by the exposure controller 58 and also the communicated exposure time periods and exposure pauses. In this case, it is possible to use a calculation of the thermal intensity distribution with the aid of the simulation module 70, or an intensity distribution measured by a measurement apparatus that is not illustrated in FIG. 1.

On the basis of the thermal intensity distribution determined, the travel generator 72 of the control device 56 generates travels X4, X5 for the manipulators M4, M5 of the two optical plates 38, 44 for the exposure pauses in such a way that the thermal intensity distribution does not change even in exposure pauses. In this case, energy can be input by the manipulators M4, M5 directly at the beginning of the exposure pause, but at least within a time period in which at most 10% of a wavefront deviation corresponding to the decrease in the thermal energy input as a result of exposure radiation forms in the projection lens (26).

In other words, the spatially resolved energy input of the exposure radiation 18 is maintained in exposure pauses by way of a corresponding thermal energy input of the manipulators M4, M5. In this way, a spatially resolved temperature profile remains substantially constant across exposure time periods and exposure pauses at both thin optical plates 38, 40. Imaging aberrations as a result of fast heating and cooling in the cycle of the exposure times are reduced very effectively by this anti-cyclic heating via the thermal manipulators M4, M5.

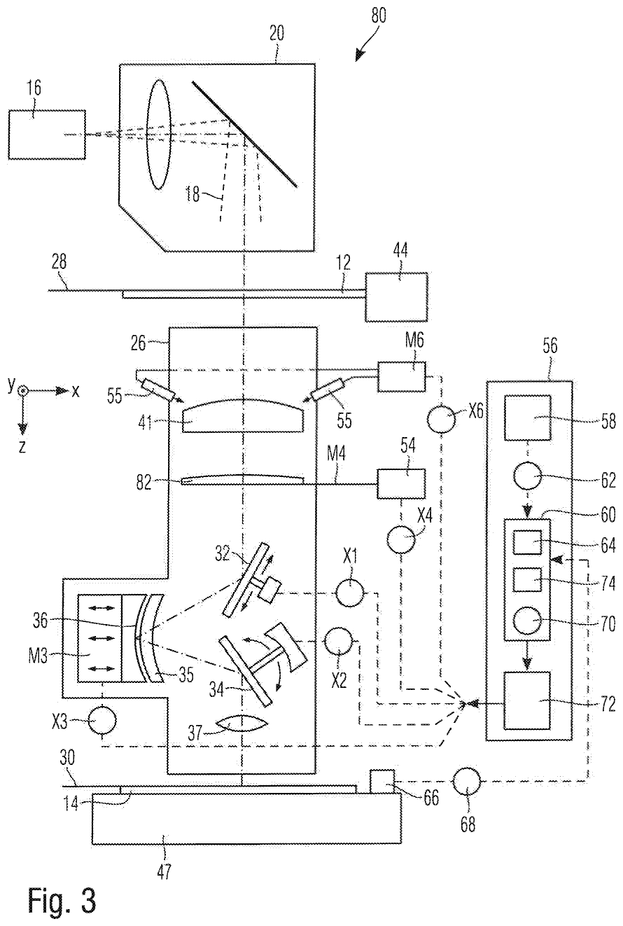

FIG. 3 illustrates a further microlithographic projection exposure apparatus 80. The projection exposure apparatus 80 corresponds to the projection exposure apparatus according to FIG. 1 with the exception that, in contrast to the projection exposure apparatus 10 according to FIG. 1, in the case of the projection exposure apparatus 80, the two plane-parallel plates 38, 40 have been removed and replaced by one thin lens element 82. The central thickness of the lens element 82 is a maximum of 10 mm. In particular, the lens element 82 has a central thickness of at most 8 mm or at most 5 mm. The lens element 82 is substantially embodied as a thin plane plate and serves as a placeholder for the two plane-parallel plates 38, 40 in the projection lens 26. For this purpose, it has substantially the same optical properties as the unheated optical plates 38, 40 and thus enables a further use of the projection lens 26 even without the plane-parallel optical plates 38, 40.

At the thin lens element 82, the effect of fast lens heating with a correspondingly fast and periodic change in imaging aberrations in the cycle of the exposure times and exposure pauses likewise occurs during operation of the projection exposure apparatus 80. For compensation of these imaging aberrations, the thin lens element 82 also contains a multiplicity of electrically heatable zones. For example, electrical conductors and resistive elements for heating are arranged at each zone.

Alternatively, the thin lens element 82, and analogously also the two optical plates 38 and 40 in accordance with FIG. 1, can also be heated by corresponding irradiation with heating radiation, for instance infrared light. Such irradiation with heating radiation can be effected analogously to the above-described irradiation of the lens element 41 via the irradiation units 55 of the manipulator M6. The heating radiation can have a wavelength that differs from the wavelength of the exposure radiation 18; alternatively, the heating radiation can also have the same wavelength as the exposure radiation 18. The heating radiation can be radiated onto the optical element transversely with respect to the beam path of the exposure radiation, i.e. from the edge of the optical element. This procedure is also referred to as “heating by transverse light”. Alternatively, with the aid of mirrors, for example, the heating radiation can be coupled into the region of the exposure beam path and thus be radiated substantially perpendicularly onto the relevant optical element, i.e. the thin lens element 82 or one of the two optical plates 38 and 40. In an alternative embodiment, the manipulator serves to direct a warm gas flow onto the relevant optical element and thus to input thermal energy into the optical element.

Analogously to the projection exposure apparatus according to FIG. 1, the determining device 74 in accordance with FIG. 3 determines a thermal intensity distribution induced by the exposure radiation 18 taking into account the communicated exposure setting 62 with exposure time periods and exposure pauses. On the basis of the thermal intensity distribution determined, the travel generator 72 generates travels X4 for a manipulator M4 of the thin lens element 82 during the exposure pauses. The travels X4 are in turn designed in such a way that the thermal intensity distribution does not change even in exposure pauses. The spatially resolved temperature profile of the thin lens element 82 remains substantially constant across many exposure time periods and exposure pauses. In this way, imaging aberrations as a result of fast lens heating are prevented when the lens element 82 is used as a placeholder for the two optical plates 38, 40.

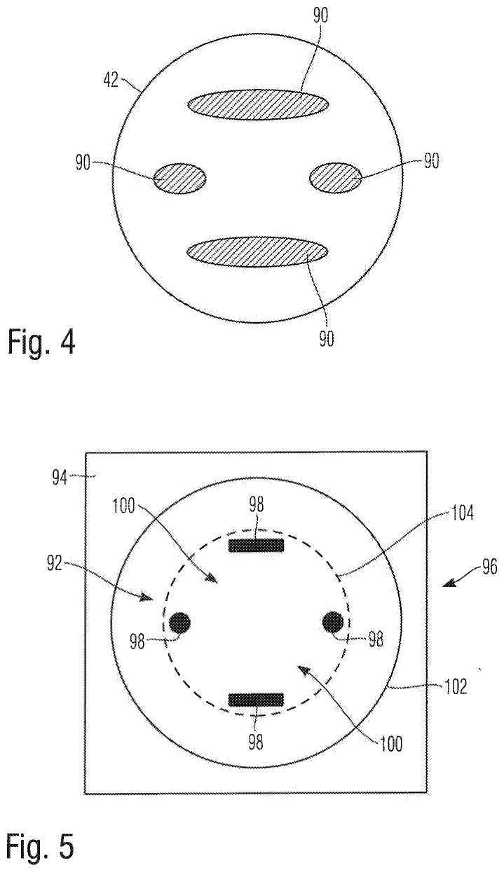

FIG. 4 shows by way of example various regions 90 having a high intensity of exposure radiation 18 in a cross section of the beam path 42 at the optical plates 38, 40 of the projection lens 26. A corresponding distribution of the radiation intensities thus serves as a placeholder for the optical plates at a thin lens element 82 as well. The intensity distribution of the exposure radiation 18 generally depends on the exposure setting selected and set in each case. Depending on the exposure setting, a higher radiation intensity occurs in different regions 90 of a cross section of the beam path 42 and a lower radiation intensity occurs in other regions. In the regions 90 having higher radiation intensity, exposure radiation is absorbed to a greater extent in the optical plates 38, 40 or the lens element 82, which in turn results in local heating of the optical plates 38, 40 or of the lens element 82 in these regions 90. During an exposure pause, these regions cool rapidly, as a result of which, together with the heating, rapid periodic changes in optical properties occur with corresponding imaging aberrations.

FIG. 5 schematically illustrates a thermal intensity distribution 92—determined for the exposure radiation according to FIG. 4—at a surface 94 of an optical element 96, for instance an optical plate 38, 40 or the lens element 82. Dark regions 98 indicate a high energy input and lighter regions 100 indicate a lower energy input. A beam path cross section is illustrated for a numerical aperture of NA=1.35, solid circle 102, and NA=0.85, dashed circle 104. This spatially resolved thermal intensity distribution 92 is determined by the determining device 74 with the aid of an illumination setting communicated by the exposure controller, wherein calculations of the simulation module 70 or measurements by a measurement apparatus may influence the determination. In exposure pauses, the manipulator controller 60 controls the manipulators M4, M5 of the optical plates 38, 40 or the manipulator M4 of the lens element 82 in such a way that as exactly as possible the same intensity distribution is produced by the manipulators. This operation of the manipulators M4, M5 anti-cyclically with respect to the exposure times prevents rapid temperature changes and thus corresponding imaging aberrations.

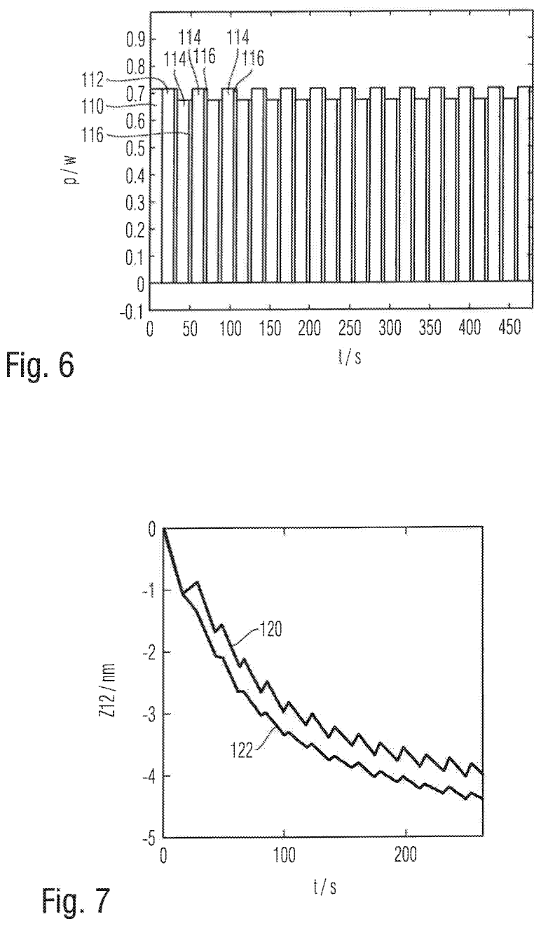

FIG. 6 shows, in a diagram, an input thermal power or an application of heat for the optical plates 38, 40 by way of exposure radiation 18 and the thermal manipulators M4, M5 during an exposure of a multiplicity of wafers, in a diagram. Time in seconds is plotted along the x-axis and power in watts is plotted along the y-axis. A first exposure 110 lasts approximately 15 s and causes a power input of just over 0.7 watt in this time period. In a succeeding exposure pause 112 for a change of wafer with a duration of approximately 10 s, heat is applied by the manipulators M4, M5 with a power of likewise just over 0.7 watt. A second and all following exposures 114 likewise last approximately 15 s, with approximately 0.72 watt and approximately 0.68 watt being input alternately. The exposure pauses 116 after each exposure 114 then each last approximately 5 s. Here the manipulators M4, M5 apply heat in each case with the power of the directly preceding exposure 114. This prevents cooling and thus a change in optical properties of the optical plates 38, 40.

FIG. 7 illustrates, in a diagram, a comparison of the temporal profile of an offset of the Zernike coefficient Z12 in the case of a projection exposure apparatus according to the disclosure and a conventional projection exposure apparatus during an exposure of a multiplicity of wafers. The Zernike coefficient Z12 together with the Zernike coefficient Z13 describes 5th order astigmatism as an imaging aberration of a projection lens. In the diagram, time in seconds is plotted along the x-axis and an offset of the Zernike coefficient Z12 in nanometers is plotted along the y-axis. The upper curve 120 shows the profile of Z12 in the case of a projection lens 26 having two thin electrically heatable optical plates 38, 40 in the case of a conventional projection exposure apparatus without anticyclic application of heat by the manipulators M4, M5. The short-term periodic fluctuations as a result of fast heating and cooling in the cycle of the exposure times and exposure pauses are clearly discernible. Overall, furthermore, general heating occurs with an increasing negative offset of Z12. In contrast thereto, the lower curve 122 of a projection exposure apparatus according to the disclosure exhibits significantly smaller periodic fluctuations since heat is applied anti-cyclically by the manipulators.

The above description of exemplary embodiments, embodiments or embodiment variants should be understood to be by way of example. The disclosure effected thereby firstly enables the person skilled in the art to understand the present disclosure and the advantages associated therewith, and secondly encompasses alterations and modifications of the described structures and methods that are also obvious in the understanding of the person skilled in the art. Therefore, all such alterations and modifications, insofar as they fall within the scope of the disclosure in accordance with the definition in the accompanying claims, and equivalents are intended to be covered by the protection of the claims.

### LIST OF REFERENCE SIGNS

10 Projection exposure apparatus
12 Mask
14 Substrate
16 Radiation source
18 Exposure radiation
20 Illumination system
22 Lens element
24 Deflection mirror
26 Projection lens
28 Object plane
30 Image plane
32 First deflection mirror
34 Second deflection mirror
35 Meniscus lens element
36 Concave mirror
37 Thin converging lens element
38 First optical plate
40 Second optical plate
41 Lens element
42 Beam path
44 Mask mount
46 Optical axis
47 Substrate mount
48 Gap
50 Gas flow
52 Zones
52 Actuating device
55 Irradiation units
56 Control device
58 Exposure controller
60 Manipulator controller
62 Illumination setting
64 Wavefront determining device
66 Wavefront measuring device
68 Measured wavefronts
70 Simulation module
72 Actuating travel generator
74 Determining device for thermal intensity distribution
80 Projection exposure apparatus
82 Thin lens element
90 Regions
92 Thermal intensity distribution
94 Surface
96 Optical element
98 Dark regions
100 Light regions
102 Solid circle
104 Dashed circle

1. An apparatus, comprising:
a projection lens comprising a plurality of optical elements configured to project structures of a mask into a substrate plane via exposure radiation, the plurality of optical elements comprising a first optical element, the projection lens further comprising a manipulator configured to provide thermal energy into the first optical element without one of the other optical elements of the projection lens being significantly heated; and
a control device configured to control the exposure radiation and the manipulator so that, for at most 15 seconds when an amount of thermal energy input into the projection lens decreases due to an exposure pause, the decrease in the amount of thermal energy input into the projection lens is at least partially compensated by an of energy input into the first optical element via the manipulator,
wherein the apparatus is a microlithographic projection exposure apparatus.

2. The apparatus of claim 1, wherein the at least partial compensation by the manipulator alters a wavefront aberration of the projection lens.

3. The apparatus of claim 1, wherein an effect on a temporal profile of an optical property of the projection lens due to the energy input via the manipulator is coordinated with an effect on the temporal profile of the optical property of the projection lens due to the exposure pause.

4. The apparatus of claim 1, wherein the first optical element provided has a subaperture ratio of at least 0.4.

5. The apparatus of claim 1, wherein the first optical element has a central thick-ness of at most 10 mm.

6. The apparatus of claim 1, wherein:
the plurality of optical elements comprises a second optical element different from the first optical element;
the first optical element has a first subaperture ratio;
the second optical element has a second subaperture ratio that differs from the first subaperture ration by at most 0.3; and
the second optical element has a central thickness of at most 10 mm.

7. The apparatus of claim 6, wherein the second optical element comprises a meniscus lens element arranged in front of a concave mirror.

8. (canceled)

9. The apparatus of claim 6, wherein at least one of the following holds:
the second optical element comprises a lens element arranged in a first third of the projection lens;
the second optical element comprises a lens element arranged in a last third of the projection lens; and
the second optical element comprises a lens element arranged in front of a concave mirror.

10. The apparatus of claim 1, wherein the exposure radiation is in the DUV wavelength range.

11. The apparatus of claim 1, further comprising a device configured to determine a thermal intensity distribution input into the first optical element via the exposure radiation during an exposure process.

12. The apparatus of claim 1, wherein the control device is configured to control the manipulator so that the energy input by the manipulator into the first optical element is spatially resolved over an optically effective area of the first optical element.

13. The apparatus of claim 1, wherein the control device is configured to effect the energy input into the first optical element via the manipulator within a time period in which at most 10% of a wave-front deviation corresponding to the decrease in the thermal energy input forms in the projection lens.

14. The apparatus of claim 1, wherein the control device is configured to effect the thermal energy input over for at least two seconds.

15. The apparatus of claim 1, wherein the first optical element comprises a plane-parallel plate.

16. The apparatus of claim 1, wherein the plurality of optical elements comprises at least two plane-parallel plates.

17. The apparatus of claim 1, wherein the manipulator comprises heating elements configured to provide the thermal energy into the first optical element.

18. The apparatus of claim 1, wherein:
the plurality of optical elements further comprises a second optical element;
the apparatus further comprises a second manipulator configured to input thermal energy into the second optical element;
the first optical element comprises a first plane parallel plate comprising a first plurality of heatable zones; and
the second optical element comprises a second plane parallel plate comprising a plurality of heatable zones.

19. (canceled)

20. The apparatus of claim 1, wherein the manipulator comprises an irradiation device configured to provide heating radiation onto the optical element.

21. A method of controlling a microlithographic projection exposure apparatus comprising a projection lens, the projection lens comprising a plurality of optical elements configured to project structures of a mask into a substrate plane via exposure radiation, the plurality of optical elements comprising a first optical element, the projection lens further comprising a manipulator configured to input of thermal energy into the first optical element without significantly heating one of further optical elements of the projection lens, the method comprising:
controlling the manipulator so that an amount of thermal energy input into the projection lens decreases due to an exposure pause is at least partially compensated by an of energy input into the first optical element via the manipulator

22. The method as claimed in claim 21, further comprising:
determining a thermal intensity distribution input into the first optical element via the exposure radiation during an exposure process by the exposure radiation; and
controlling the manipulator based on the determined thermal intensity distribution.
